(19) United States
(12) Patent Application Publication
(10) Pub. No.: US 2026/0252754 A1
(43) Pub. Date: Aug. 27, 2026

(54) METHOD FOR COMPONENT DESIGN IN A MULTIPLE COMPONENT ASSEMBLY

(71) Applicant: FCA US LLC, Auburn Hills, MI (US)

(72) Inventors: Pavan K Paruchuru, Auburn Hills, MI (US); Nitin Sharma, Auburn Hills, MI (US); Malli Kartheek Yalamanchili, Auburn Hills, MI (US); Ramachandra Bhat, Auburn Hills, MI (US); Abhishek Paul, Auburn Hills, MI (US)

(21) Appl. No.: 19/065,479

(22) Filed: Feb. 27, 2025

(51) Int. Cl. G06F 30/15; G06F 30/17

(52) U.S. Cl. CPC G06F 30/15; G06F 30/17

(57) ABSTRACT

A method of computer aided component design in an assembly, includes providing a first design having multiple components, determining a joint area in the first design that is a portion of the first design in which a first component is or will be connected to a second component, locking the joint area within the first design so that the shape of the portion within the joint area of the one or more of the multiple components does not change, and changing the first design to a second design. The design change is accomplished by changing the location of at least one feature relative to the joint area or by moving the joint area relative to the at least one feature, where the at least one feature is a portion of at least one of the multiple components that is not within the joint area.

### FIELD

The present disclosure relates to methods for component design in a multiple component assembly of a vehicle.

### BACKGROUND

Components for vehicles are developed with computer-aided design programs that provide a digital representation of the component design. Various simulated tests may be run on components and assemblies of components to determine component performance under different loads, temperatures, and the like. It is very time consuming and expensive to develop detailed design data for multiple component systems, especially those that undergo significant simulations and other testing to ensure compliance with various requirements.

### SUMMARY

In at least some implementations, a method of computer aided component design in a multiple component assembly, includes providing a digital representation of a first design having multiple components, determining a joint area in the digital representation of the first design wherein the joint area is a portion of the first design in which a first component is or will be connected to a second component, locking the joint area within the digital representation of the first design so that the shape of the portion within the joint area of the one or more of the multiple components does not change, and digitally changing the first design to a second design. The design change is accomplished by changing the location of at least one feature relative to the joint area or by moving the joint area relative to the at least one feature, where the at least one feature is a portion of at least one of the multiple components that is not within the joint area.

In at least some implementations, the at least one feature includes a first part of a component that has a second part that defines part of the joint area.

In at least some implementations, the multiple components include at least two metal frame members that define part of a vehicle structural assembly, and in the first design and the second design, the two metal frame members are connected together in the joint area.

In at least some implementations, the joint area is defined with a metal frame component that is one of the multiple components, and the joint area includes a connection feature defined at least in part by the metal frame component.

In at least some implementations, the multiple components include at least two metal frame members that define part of a vehicle structural assembly, and the step of changing the first design to the second design includes changing the shape of at least one of the two metal frame members in an area outside of the joint area.

In at least some implementations, the first design includes multiple joint areas and the step of locking the joint area includes locking each of the multiple joint areas, and the step of changing the first design to the second design includes changing the shape of multiple features of one or more of the multiple components that are not within any of the multiple joint areas. In at least some implementations, the method includes adjusting the shape of one or more of the multiple features to mesh with one or more of the multiple joint areas to define a final shape of the components in the second design.

In at least some implementations, the step of changing the first design to the second design includes moving at least one of the joint areas from a location or orientation in the first design to a different location or different orientation in the second design. In at least some implementations, a distance between two adjacent joint areas is different in the first design than in the second design.

In at least some implementations, the first design includes multiple joint areas and the step of locking the joint area includes locking each of the multiple joint areas, and the step of changing the first design to the second design includes moving at least one of the multiple joint areas and thereby changing the shape of at least one feature of one or more of the multiple components that are contiguous with the at least one joint area that is moved and are not within any of the multiple joint areas.

In at least some implementations, the method includes adjusting the shape of the at least one feature after moving the at least one of the multiple joint areas. In at least some implementations, adjusting the shape of the at least one feature is done to meet at least one threshold relating to the shape of the at least one feature or the shape of the location where the at least one feature merges with an adjacent one of the joint areas. In at least some implementations, the second design includes a mesh overlaid onto the multiple components and including the joint areas, and wherein movement of one of the joint areas deforms the mesh and causes movement of adjacent components within an area of the mesh including the one joint area that is moved.

In at least some implementations, a method of computer aided component design in a multiple component assembly includes providing a first design having multiple components, determining multiple joint areas in the first design wherein the multiple joint areas are each a portion of the first design in which a first component is or will be connected to a second component, locking each of the multiple joint areas within the first design so that the shape of the portion within each of the multiple joint areas of the one or more of the multiple components does not change, and changing the first design to a second design by changing the location of at least one of the multiple joint areas and by changing the shape of at least one of the first component and the second component a portion of which defines part of the at least one of the multiple joint areas.

Further areas of applicability of the present disclosure will become apparent from the detailed description, claims and drawings provided hereinafter. It should be understood that the summary and detailed description, including the disclosed embodiments and drawings, are merely exemplary in nature intended for purposes of illustration only and are not intended to limit the scope of the invention, its application or use. Thus, variations that do not depart from the gist of the disclosure are intended to be within the scope of the invention.

### BRIEF DESCRIPTION OF THE DRAWINGS

FIG. 1 is a perspective view of a digital representation of part of a vehicle structural assembly;

FIG. 2 is a side view of part of the assembly shown in FIG. 1;

FIG. 3 is similar to FIG. 2 and shows a joint area moved to a new location pursuant to a second design;

FIG. 4 is a flow chart of a method for developing computer aided component design in a multiple component assembly, starting with a first design and modifying the first design to achieve a second design; and

FIG. 5 is a flow chart of methods for further design development prior to more detailed computer-aided design development.

### DETAILED DESCRIPTION

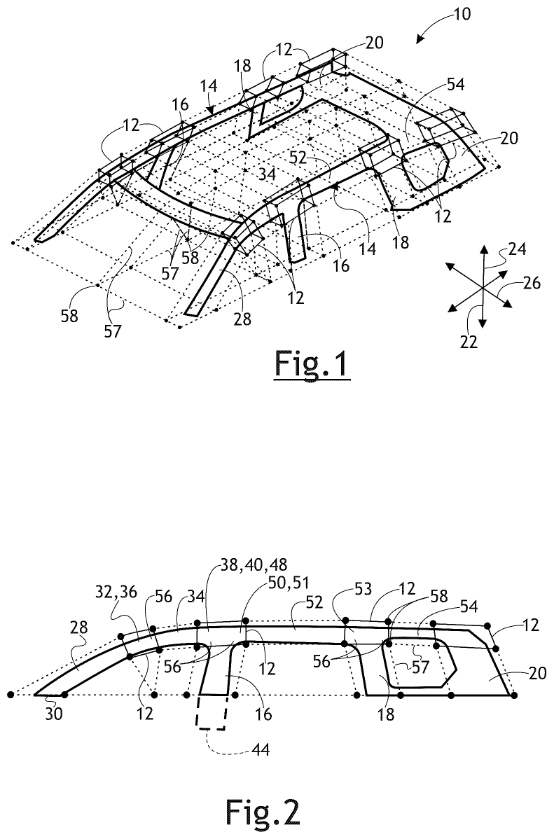

Referring in more detail to the drawings, FIG. 1 shows a digital representation of part of a vehicle structural assembly 10 that includes several structural members connected together in joint areas 12. The digital representation can be developed or manipulated in computer-aided engineering (CAE) and/or computer-aided design (CAD) programs. Beyond the shape of the structural members, the programs may contain information regarding the specific dimensions and materials of the members, including information about the components or manner in which the members are connected together, such as by fasteners (e.g. bolts, rivets), interlocked features, welds, adhesives and the like. With this information, computer simulations can be run to test the integrity of a vehicle structural assembly 10 built according to the information provided to the programs. Simulated loads, temperatures and the like can be applied to the structure to determine if the structure is suitable for the intended application or use.

In the example shown in FIGS. 1 and 2, the vehicle structural assembly 10 includes two upper side rails or roof rails 14 that extend in a fore-aft direction of the vehicle and, in use, are coupled to multiple pillars 15, 16, 18, 20 and a roof panel (not shown) or roof assembly. Here, the fore-aft direction extends between the front and rear of the vehicle (and is shown by arrow 22), “upper” is with reference to a vertical direction that extends between the roof and a floor of the vehicle (shown by arrow 24), and “side” is with reference to a cross-car direction that extends between the left and right sides of the vehicle (shown by arrow 26).

As shown in FIG. 2, a first structural member may be a first rail part 28 that defines a forward portion of a roof rail 14, extends in the fore-aft direction, has a width in the cross-car direction, a height in the vertical direction, and may provide support for, among other things, a side of a windshield of the vehicle. An A-pillar 15 is defined in this example by a first rail part 28 that slopes upwardly from a first or forward end 30 at or near a hood of the vehicle and forward side body panels at the front of the vehicle to a second end 32 that is connected to a second structural member that may be a second rail part 34. The second rail part 34 may be constructed and arranged similarly to the first rail part 28 (e.g. oriented in fore-aft direction and may have similar cross-car and vertical width and height), is connected at a first end 36 to the second end 32 of the first rail part 28, at a second end 38 to a first end 40 of a third structural member, often called the B-pillar 16, and may have a bend between its ends 36, 38 to smoothly transition vertically between the components 28, 34.

The B-pillar 16 extends vertically from the first end 40 to a second end 44 that is lower than the first end 40 and may be coupled to a rail or other component (not shown) defining part of the side of the vehicle structure. The B-pillar 16 has a thickness in the cross-car direction and a width in the fore-aft direction. The first end 40 of the B-pillar 16 has a first side 48 that is connected to the second rail part 34 and a second side 50 spaced in the fore-aft direction from the first side 48 and arranged to be connected to a first end 51 of a fourth structural member which may be a third rail part 52. The third rail part 52 may be constructed and arranged similarly to the first and second rail parts 28, 34 and may span a fore-aft distance between the B-pillar 16 and a second end 53 connected to a fifth structural member, which in this example is a second or C-pillar 18 of the vehicle structural assembly 10. The C-pillar 18 may be constructed and arranged similarly to the B-pillar 16. The roof rail 14 and other structural members may continue along the side of the vehicle toward the rear of the vehicle, with a fourth rail part 54 connected between the C-pillar 18 and a D-pillar 20, in known manner.

Each structural member 16, 18, 20, 28, 34, 52, 54 is connected to at least one other structural member in a joint area 12. In at least some implementations, the joint areas 12 are defined to include at least an area of direct overlap between adjacent structural members including the area in which one or more connection features are located, and may also include a predetermined area outboard of the location of the connection features. The connection feature or features include, by way of non-limiting examples, the fasteners (e.g. bolts, rivets), interlocked structures, welds, and adhesives. For example, the first structural member (e.g. first rail part 26) and second structural member (e.g. second rail part 34) have portions that overlap in the fore-aft direction and the joint area 12 defined between them includes the area of overlap in the fore-aft direction and a predetermined area outboard of the area of overlap. In at least some implementations, the area outboard of the overlap is between about 10 mm to 100 mm.

The joint area 12, including any area outboard of the overlap between components, may be selected based upon one or more thresholds. For example, an angle or radius or the like of an area leading to the joint area 12. By way of a non-limiting example, too sharp of an angle or too small of a radius may reduce the strength/integrity of a structural component or the joint between structural components. Thus, the joint area 12 may be selected to include a radiused or angled area 56 outboard of the overlap between components to ensure a suitable angle/orientation of the area adjacent to a joint.

It can be very time consuming to develop the digital data for an entire vehicle structural assembly 10 (only a part of which is shown in FIG. 1), including specific dimensions and data for individual structural members as well as the manner and specific location/orientation of the joints/connections between components. After this data is developed and an initial design is completed, at least to the extent necessary for simulation or other testing, the design may be tested via one or more simulation programs. Various thresholds may be provided for part movement or deflections under load, tolerances for components and the like, and compared to the performance of the design during the simulations/testing. Component or areas of components that do not perform as intended are then modified, which can involve changing the shape, size, materials or other properties of multiple members in the design. Changing the shape of a member can cause changes to a joint area 12 between that member and one or more other members, can change the shape and/or location of connection features, like bolt or rivet holes, and thereby change the connection characteristics of that joint in the design. After the changes are made, the simulation and testing is then run again on the modified design and further iterations may be accomplished to finally achieve a design that satisfies the design criteria and component thresholds and assembly thresholds.

The final design data from the simulation program(s) is then provided to a CAD design program for completion of a final design for the individual components, as well as manufacturing and assembly details for the overall structure. The data generated in the CAD program may be used as specifications for the components, to facilitate building the components and to provide a plan for assembly of the components to ensure the entire structure can be built and assembled as intended.

In at least some implementations, to achieve a final design more efficiently, in less time and at lower cost, a method of developing computer aided component design in a multiple component assembly starts with a first design of a vehicle or portion thereof that is similar to a desired final design of the vehicle or portion thereof. FIG. 4 illustrates a flowchart of a representative method 60 with obtaining/providing a first design shown in step 62. In the method, a digital representation of the first design having multiple components is provided, and in step 64, one or more joint areas 12 are determined. The digital representation may include all or some of the data from a computer aided engineering and/or design program. The digital representation may be all or part of a vehicle system, such as all or part of the vehicle structural assembly. In the digital representation of the first design, the joint areas 12 include, for example and as set forth earlier, the portions of the first design in which one component is or will be connected to a second component. As shown in FIGS. 1 and 2, the digital design may include a grid or mesh layout in which a mesh is overlaid on the design, with lines 57 of the mesh and nodes 58 at intersections of the lines being movable to move design elements tied thereto in the digital design. In this example, the joint areas 12 can be defined by lines and nodes defining a cubical or other three-dimensional shape capturing or surrounding the desired areas. With the overlaid mesh or grid, movement of one of the joint areas deforms the mesh and causes movement of at least a portion of one or more adjacent components within an area of the mesh including the one joint area that is moved. Thus, the components can be morphed and then the mesh and design elements adjusted to provide a desired shape of all components in the design. Of course, other techniques for changing the design may be used, as desired.

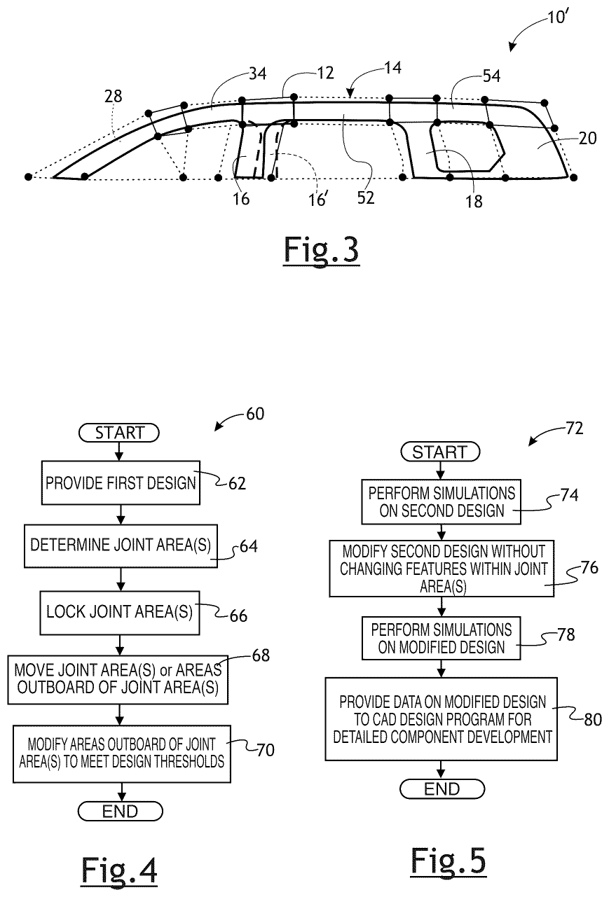

With the joint areas 12 determined, in step 66, the joint areas 12 are then locked in the design, e.g. within the digital representation of the first design, so that the shape of the component portions within the joint area 12 does not change when the first design is modified to produce a second design, which may be the final design or a design iteration leading to the final design. Locking the joint areas 12 means that the component structures and features within the joint area 12 cannot be changed while areas of the components outboard of the joint areas 12 are changed. The entire area within each joint area 12 may move together, but features within a joint area 12 do not move relative to each other, as generally shown in FIG. 3. This maintains, by way of non-limiting examples, the same thickness, width and length of the portion of each component in a joint area 12, the same relationships between the portions of multiple components in a joint area 12, and the same location of features in the portion of each component in the joint area 12. By way of an example, surfaces to be welded together or holes in the joint area 12 through which fasteners are received remain in the same location within the joint area 12 and relative to each other in the joint area 12.

Without the joint areas 12 being locked in the design, upon changing the shape of portions of the design, the portions of components in a joint area 12 would change, and the location of connection features would change, the thickness or other dimension would change and the structural integrity of the joint area 12 could change. Because, in at least some implementations, the first design is a previously tested and approved design in which the joint areas 12 were already tested and approved, and manufacture and assembly of the components including the joint areas 12 already proven, changing the joint areas 12 can cause many issues not limited to changing the structural integrity of these areas, but also requiring different assembly fixtures and the like. Thus, after a modification of the first design, the changed joint areas 12 would have to be carefully reviewed and revised which takes considerable time and effort. The portions of components between joint areas 12 are, in the example of a vehicle structural system, of simpler construction and other components do not as directly depend upon their configuration. Thus, changes in these areas are easier to make in the design and have less effect on the design as a whole.

With the joint areas 12 locked, the method enables generation in step 68 of the second design by digitally changing the first design to the second design by changing the location of at least one feature relative to one or more joint areas 12 or by moving one or more joint areas 12 relative to the at least one feature, or both of these. One example of a design change is shown by comparison of FIGS. 2 and 3. In FIG. 3, a second design of the vehicle structural assembly 10′ is shown in which the joint area 12 associated with the first end 40 of the B-pillar 16 has been moved rearwardly, in the fore-aft direction as compared to the first design shown in FIG. 2. In FIG. 3, the former position of the B-pillar is shown by reference numeral 16 and the new position is shown by reference numeral 16′. The rest of the B-pillar 16′, as shown in FIG. 3, has also been shifted rearwardly and this movement may require adjustments to structures to which the other end 44 of the B-pillar is connected. Additionally, the second rail part 34 and third rail part 52 are correspondingly lengthened and shortened, respectively, to match the movement of the joint area 12. At least some of the feature or features that are changed are portions of the assembly that are not within the joint area 12 (e.g. rail parts 34 and 52), and thus, do not have features dependent upon their specific location. As noted, these features could be a dimension of a portion of a component outboard of a joint area 12, for example a length, width or thickness of part of the component, or a shape of that portion of the component to increase or decrease a bend or angle to match up one or more ends or endpoints of the component with one or more joint areas 12.

In at least some implementations, the components in the digital representation of the design may remain connected together during the movement of one or more features of the design. In this way, the design can be “morphed” from the first design 10 at least part of the way to the second design 10′. By this it is meant that, for example, moving a joint area 12 vertically downward will cause the portions of the components outboard of the joint area 12 to change shape to remain connected to the moved joint area 12, rather than the areas outboard of the joint area 12 remaining in their locations such that the joint area 12 would be disconnected from the areas outboard of the joint area 12 upon movement of the joint area 12. Thus, the areas outboard of a moved joint area 12 will bend or otherwise change location. Minor movements of the joint area 12 can be easily accommodated with little to no change required to the areas outboard of the joint area 12, while larger movements may require adjustments to the areas outboard of the joint area 12, as noted in step 70.

With the joint areas 12 remaining undisturbed, the joint areas 12 themselves often do not require any adjustments. Further, components that may be connected to the components within the joint areas 12 need not be changed. In this regard, various brackets and components may be coupled to the frame members within the joint areas 12. For example, seat belt anchors for a seat belt retractor or pillar loop, exterior body panels or trim components, sensors, actuators, suspension or other vehicle system components, interior trim components and the like can utilize the same connection interfaces with the components in the joint areas 12. While a joint area 12 is described above as including a region in which two structural components are connected together in the design, the joint areas 12 may also include portions of a component that includes a connection interface for a component not within the digital representation of the design, a component that will be connected to the connection interface later in the vehicle assembly process. In this way, a mating or complementary connection interface of the later provided component need not be changed and suitable connection to the joint area 12 is assured because the location of features in the joint area 12 that define the connection interface has not changed.

In at least some implementations, the multiple components include at least two metal frame members that define part of a vehicle structural assembly, and wherein, in the first design and the second design, the two metal frame members are connected together in the joint area 12. When changing the first design to the second design, the shape of at least one of the two metal frame members changes in an area outside of the joint area 12. The first design may include multiple joint areas 12 and one and up to each of the multiple joint areas 12 may be locked/prevented from being changed as the first design is changed.

As noted earlier, the first design may be changed by moving one or more joint areas 12, or by moving portions of components outboard of the joint areas 12. In the example of moving one or more joint areas 12, an angle/orientation and/or a distance between two adjacent joint areas 12 can be different in the first design than in the second design.

After such initial adjustment to the design, the shape of one or more of the multiple features may be adjusted to mesh with one or more of the multiple joint areas 12 to define a final shape of the components in the second design. Adjusting the shape of the at least one feature may be done, in at least some implementations, to meet at least one threshold relating to the shape of at least one feature or the shape of the location where the at least one feature merges with an adjacent one of the joint areas 12. For example, to maintain part strength, such as by ensuring suitable strength for a given size/length of a part or to avoid sharp angles or bends that may be difficult to manufacture, or difficult to use with adjacent components, or cause areas of high stress concentration or the like. In this way, the shape/design of multiple components can be changed together, rather than changing each component separately and then later providing the separate components together in a digital representation. Changing or morphing components at the same time facilitates meshing and matching of component features and reduces details that need to be cleaned-up later.

FIG. 5 illustrates a flowchart of a representative further method 72 which begins in step 74 with testing of the design produced by method 60. This may be done in various CAE programs, as is known. Based on the results of the simulations and testing, the design may be modified in step 76, as required to meet design criteria and thresholds, and for any desired improvements. The modified design can be further tested, in step 78. Once a design is shown to be satisfactory from simulations/testing, the design can be provided for further development, such as with detailed CAD work to move to a production ready design as described herein and as noted in step 80.

Joint areas 12 within a vehicle design are regions in which two or more components are connected together, at least in a final design or assembly of a vehicle. By preventing change within one or more of the joint areas 12 as the design is changed from a first design to a second design, completion of the second design, including components that are assembled to components within the second design, is simplified. Already designed connections and the structural integrity within the joint areas 12 can be maintained, as can manufacturing and assembly steps with regard to overlapping and connected components within the design. These are some examples of the efficiencies that can be gained by utilizing a first design and limiting change to the joint areas 12 of the design while morphing the first design to a second design. The second design can then be prepared more efficiently for computer simulation and related testing to ensure the integrity of the design. Additionally, changes needed after such simulation and testing can be done with the same methods to ensure efficiency in the design changes and further simulation and testing. Finally, the more detailed CAD data for the joint areas 12 can also be maintained so that final design of the new design can be also be done more efficiently.

What is claimed is:

1. A method of computer aided component design in a multiple component assembly, the method comprising:
providing a digital representation of a first design having multiple components;
determining a joint area in the digital representation of the first design wherein the joint area is a portion of the first design in which a first component is or will be connected to a second component;
locking the joint area within the digital representation of the first design so that the shape of the portion within the joint area of the one or more of the multiple components does not change; and
digitally changing the first design to a second design by changing the location of at least one feature relative to the joint area or by moving the joint area relative to the at least one feature, where the at least one feature is a portion of at least one of the multiple components that is not within the joint area.

2. The method of claim 1 wherein the at least one feature includes a first part of a component that has a second part that defines part of the joint area.

3. The method of claim 1 wherein the multiple components include at least two metal frame members that define part of a vehicle structural assembly, and wherein, in the first design and the second design, the two metal frame members are connected together in the joint area.

4. The method of claim 1 wherein the joint area is defined with a metal frame component that is one of the multiple components, and wherein the joint area includes a connection feature defined at least in part by the metal frame component.

5. The method of claim 1 wherein the multiple components include at least two metal frame members that define part of a vehicle structural assembly, and the step of changing the first design to the second design includes changing the shape of at least one of the two metal frame members in an area outside of the joint area.

6. The method of claim 1 wherein the first design includes multiple joint areas and the step of locking the joint area includes locking each of the multiple joint areas, and the step of changing the first design to the second design includes changing the shape of multiple features of one or more of the multiple components that are not within any of the multiple joint areas.

7. The method of claim 6 which also includes adjusting the shape of one or more of the multiple features to mesh with one or more of the multiple joint areas to define a final shape of the components in the second design.

8. The method of claim 6 wherein the step of changing the first design to the second design includes moving at least one of the joint areas from a location or orientation in the first design to a different location or different orientation in the second design.

9. The method of claim 8 wherein a distance between two adjacent joint areas is different in the first design than in the second design.

10. The method of claim 1 wherein the first design includes multiple joint areas and the step of locking the joint area includes locking each of the multiple joint areas, and the step of changing the first design to the second design includes moving at least one of the multiple joint areas and thereby changing the shape of at least one feature of one or more of the multiple components that are contiguous with the at least one joint area that is moved and are not within any of the multiple joint areas.

11. The method of claim 10 which also includes adjusting the shape of the at least one feature after moving the at least one of the multiple joint areas.

12. The method of claim 11 wherein adjusting the shape of the at least one feature is done to meet at least one threshold relating to the shape of the at least one feature or the shape of the location where the at least one feature merges with an adjacent one of the joint areas.

13. The method of claim 11 wherein the second design includes a mesh overlaid onto the multiple components and including the joint areas, and wherein movement of one of the joint areas deforms the mesh and causes movement of adjacent components within an area of the mesh including the one joint area that is moved.

14. A method of computer aided component design in a multiple component assembly, the method comprising:
providing a first design having multiple components;
determining multiple joint areas in the first design wherein the multiple joint areas are each a portion of the first design in which a first component is or will be connected to a second component;
locking each of the multiple joint areas within the first design so that the shape of the portion within each of the multiple joint areas of the one or more of the multiple components does not change; and
changing the first design to a second design by changing the location of at least one of the multiple joint areas and by changing the shape of at least one of the first component and the second component a portion of which defines part of the at least one of the multiple joint areas.

15. The method of claim 14 wherein changing the shape of the at least one feature is done to meet at least one threshold relating to the shape of the at least one feature or the shape of the location where the at least one feature merges with the at least one of the multiple joint areas.

16. The method of claim 11 wherein one or both of the first design and the second design includes a mesh overlaid onto the multiple components and including the joint areas, and wherein movement of one of the multiple joint areas deforms the mesh and causes movement of adjacent components within an area of the mesh including the joint area that is moved.

17. The method of claim 14 wherein the first component and the second component are both metal frame members that define part of a vehicle structural assembly, and wherein, in the first design and the second design, the first component and the second component are connected together in one of the multiple joint areas.

18. The method of claim 14 wherein at least one of the multiple joint areas is defined by part of a metal frame component that is one of the multiple components, and wherein the joint area includes a connection feature defined at least in part by the metal frame component.

19. The method of claim 14 wherein the multiple components include at least two metal frame members that define part of a vehicle structural assembly, and the step of changing the first design to the second design includes changing the shape of at least one of the two metal frame members in an area not within the multiple joint areas.
